(19) United States
(12) Patent Application Publication
(10) Pub. No.: US 2022/0067272 A1
(43) Pub. Date: Mar. 3, 2022

(54) Robotic Process Automation Systems and Methods Using A Helper Spreadsheet

(71) Applicant: UiPath Inc., New York, NY (US)

(72) Inventor: Bogdan RIPA, Bucuresti (RO)

(21) Appl. No.: 17/008,944

(22) Filed: Sep. 1, 2020

(51) Int. Cl. G06F 40/18; G06F 30/12; G06F 3/0482

(52) U.S. Cl. CPC G06F 40/18; B25J 9/1656; G06F 3/0482; G06F 30/12

(57) ABSTRACT

Some embodiments of robotic process automation (RPA) design software facilitate the programming of RPA robots by supplying the developer with a universal helper spreadsheet pre-filled with formulae for carrying out a plurality of data conversions and/or manipulations, such as changing the format of dates and numbers and various calendar calculations. When automation activities call for such data manipulation, the helper spreadsheet enables even non-technical developers to program RPA robots using their spreadsheet expertise and intuitive design tools, instead of coding per se.

### BACKGROUND

The invention relates to robotic process automation (RPA), and in particular to facilitating the programming of RPA robots by using a helper spreadsheet.

RPA is an emerging field of information technology aimed at improving productivity by automating repetitive computing tasks, thus freeing human operators to perform more intellectually sophisticated and/or creative activities. Notable tasks targeted for automation include extracting structured data from documents and interacting with user interfaces, for instance to fill in forms, among others.

A distinct prong of RPA development is directed at simplifying the programming and management of software robots, with the ultimate goal of extending the reach of RPA technology to users that lack advanced programming skills or training. One way of making RPA more accessible is the development of RPA-oriented integrated development environments (IDEs) which allow the programming of robots via graphical user interface (GUI) tools, instead of coding per se. There is a strong interest in making such GUI tools as intuitive and user-friendly as possible, to attract a broad audience of developers.

### SUMMARY

According to one aspect, a method comprises employing at least one hardware processor of a computer system to expose a RPA design interface to a user. The RPA design interface comprises an activity menu for selecting robotic activities for interacting with user-provided spreadsheets, and an interface element which, when activated by the user, causes the at least one hardware processor to invoke a universal helper spreadsheet comprising a standardized spreadsheet common to multiple user accounts, the universal helper spreadsheet pre-filled with a set of formulae for carrying out data manipulations. The method further comprises receiving a user input indicating a selected input cell and a selected output cell of the universal helper spreadsheet, and in response, outputting a computer-readable specification of an RPA robot. The RPA robot is configured to write a data item to a runtime instance of the selected input cell, invoke a spreadsheet application to compute a content of a runtime instance of the selected output cell, and perform an action that mimics a computer task carried out by a human operator, the action performed according to the content of the runtime instance of the output cell.

According to another aspect, a computer system comprises at least one hardware processor configured to expose a RPA design interface to a user. The RPA design interface comprises an activity menu for selecting robotic activities for interacting with user-provided spreadsheets, and an interface element which, when activated by the user, causes the at least one hardware processor to invoke a universal helper spreadsheet comprising a standardized spreadsheet common to multiple user accounts, the universal helper spreadsheet pre-filled with a set of formulae for carrying out data manipulations. The at least one hardware processor is further configured to receive a user input indicating a selected input cell and a selected output cell of the universal helper spreadsheet, and in response, output a computer-readable specification of an RPA robot. The RPA robot is configured to write a data item to a runtime instance of the selected input cell, invoke a spreadsheet application to compute a content of a runtime instance of the selected output cell, and perform an action that mimics a computer task carried out by a human operator, the action performed according to the content of the runtime instance of the output cell.

According to another aspect, a non-transitory computer-readable medium stores instructions which, when executed by at least one hardware processor of a computer system, cause the computer system to expose a RPA design interface to a user. The RPA design interface comprises an activity menu for selecting robotic activities for interacting with user-provided spreadsheets, and an interface element which, when activated by the user, causes the computer system to invoke a universal helper spreadsheet comprising a standardized spreadsheet common to multiple user accounts, the universal helper spreadsheet pre-filled with a set of formulae for carrying out data manipulations. The instructions further cause the computer system to receive a user input indicating a selected input cell and a selected output cell of the universal helper spreadsheet, and in response, output a computer-readable specification of an RPA robot. The RPA robot is configured to write a data item to a runtime instance of the selected input cell, invoke a spreadsheet application to compute a content of a runtime instance of the selected output cell, and perform an action that mimics a computer task carried out by a human operator, the action performed according to the content of the runtime instance of the output cell.

### BRIEF DESCRIPTION OF THE DRAWINGS

The foregoing aspects and advantages of the present invention will become better understood upon reading the following detailed description and upon reference to the drawings where:

FIG. 1 shows an exemplary robotic process automation (RPA) environment according to some embodiments of the present invention.

FIG. 2 illustrates exemplary components and operation of an RPA robot and orchestrator according to some embodiments of the present invention.

FIG. 3 shows a variety of RPA host systems according to some embodiments of the present invention.

FIG. 4 shows exemplary RPA components executing on an RPA host according to some embodiments of the present invention.

FIG. 5 shows an exemplary user interface (UI) having a plurality of UI elements according to some embodiments of the present invention.

FIG. 6 illustrates an exemplary robot design interface exposed by an RPA design application according to some embodiments of the present invention.

FIG. 7 shows an exemplary universal helper spreadsheet according to some embodiments of the present invention.

FIG. 8 shows an exemplary sequence of steps performed by the RPA design application according to some embodiments of the present invention.

FIG. 9 illustrates exemplary cascading menus for configuring an RPA activity using the universal helper spreadsheet according to some embodiments of the present invention.

FIG. 10 shows an excerpt of a workflow comprising a sequence of exemplary RPA activities configured according to the universal helper spreadsheet.

FIG. 11 shows an exemplary sequence of steps performed by an RPA robot according to some embodiments of the present invention.

FIG. 12 shows an exemplary hardware configuration of a computer system configured to execute some embodiments of the present invention.

### DETAILED DESCRIPTION OF PREFERRED EMBODIMENTS

In the following description, it is understood that all recited connections between structures can be direct operative connections or indirect operative connections through intermediary structures. A set of elements includes one or more elements. Any recitation of an element is understood to refer to at least one element. A plurality of elements includes at least two elements. Any use of ‘or’ is meant as a nonexclusive or. Unless otherwise required, any described method steps need not be necessarily performed in a particular illustrated order. A first element (e.g. data) derived from a second element encompasses a first element equal to the second element, as well as a first element generated by processing the second element and optionally other data. Making a determination or decision according to a parameter encompasses making the determination or decision according to the parameter and optionally according to other data. Unless otherwise specified, an indicator of some quantity/data may be the quantity/data itself, or an indicator different from the quantity/data itself. A computer program is a sequence of processor instructions carrying out a task. Computer programs described in some embodiments of the present invention may be stand-alone software entities or sub-entities (e.g., subroutines, libraries) of other computer programs. The term ‘database’ is used herein to denote any organized, searchable collection of data. Computer-readable media encompass non-transitory media such as magnetic, optic, and semiconductor storage media (e.g. hard drives, optical disks, flash memory, DRAM), as well as communication links such as conductive cables and fiber optic links. According to some embodiments, the present invention provides, inter alia, computer systems comprising hardware (e.g. one or more processors) programmed to perform the methods described herein, as well as computer-readable media encoding instructions to perform the methods described herein.

The following description illustrates embodiments of the invention by way of example and not necessarily by way of limitation.

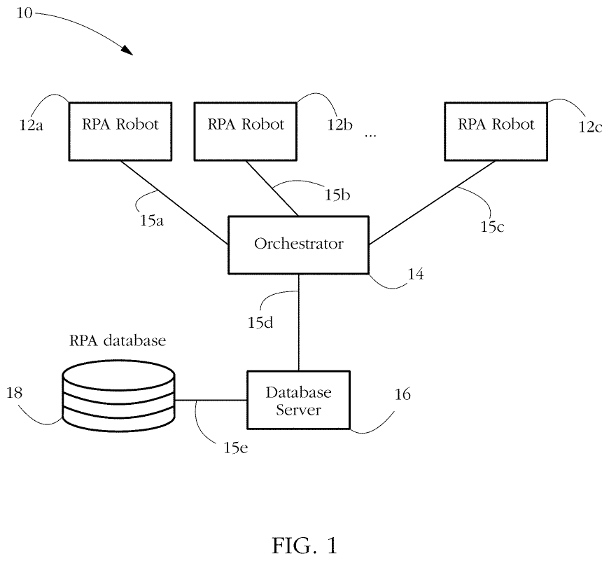

FIG. 1 shows an exemplary robotic process automation (RPA) environment 10 according to some embodiments of the present invention. Environment 10 comprises various software components which collaborate to achieve the automation of a particular task. In an exemplary RPA scenario, an employee of a company uses a business application (e.g., word processor, spreadsheet editor, browser, email application) to perform a repetitive task, for instance to issue invoices to various clients. To actually carry out the respective task, the employee performs a sequence of operations/actions, which is herein deemed a process. Exemplary operations forming a part of an invoice-issuing process may include opening a Microsoft Excel® spreadsheet, looking up company details of a client, copying the respective details into an invoice template, filling out invoice fields indicating the purchased items, switching over to an email application, composing an email message to the respective client, attaching the newly created invoice to the respective email message, and clicking a ‘Send’ button. Various elements of RPA environment 10 may automate the respective process by mimicking the set of operations performed by the respective human operator in the course of carrying out the respective task.

Mimicking a human operation/action is herein understood to encompass reproducing the sequence of computing events that occur when a human operator performs the respective operation/action on the computer, as well as reproducing a result of the human operator's performing the respective operation on the computer. For instance, mimicking an action of clicking a button of a graphical user interface may comprise having the operating system move the mouse pointer to the respective button and generating a mouse click event, or may alternatively comprise toggling the respective GUI button itself to a clicked state.

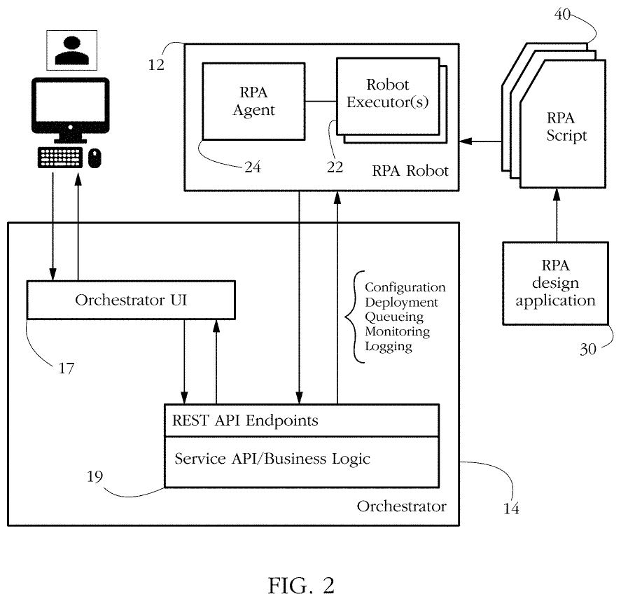

Processes typically targeted for such automation include processing of payments, invoicing, communicating with business clients (e.g., distribution of newsletters and/or product offerings), internal communication (e.g., memos, scheduling of meetings and/or tasks), auditing, and payroll processing, among others. In some embodiments, a dedicated RPA design application 30 (FIG. 2) enables a human developer to design a software robot to implement a workflow that effectively automates a target process. A workflow typically comprises a sequence of custom automation steps, herein deemed activities. Workflows may be nested and/or embedded. Each activity may include an action performed by the robot, such as clicking a button, reading a file, writing to a spreadsheet cell, etc. In some embodiments, RPA design application 30 exposes a user interface and set of tools that give the developer control of the execution order and the relationship between activities of a workflow. One commercial example of an embodiment of RPA design application 30 is UiPath StudioX™.

Some types of workflows may include, but are not limited to, sequences, flowcharts, finite state machines (FSMs), and/or global exception handlers. Sequences may be particularly suitable for linear processes, enabling flow from one activity to another without cluttering a workflow. Flowcharts may be particularly suitable to more complex business logic, enabling integration of decisions and connection of activities in a more diverse manner through multiple branching logic operators. FSMs may be particularly suitable for large workflows. FSMs may use a finite number of states in their execution, which are triggered by a condition (i.e., transition) or an activity. Global exception handlers may be particularly suitable for determining workflow behavior when encountering an execution error and for debugging processes.

Once a workflow is developed, it may be encoded in computer-readable form as a set of RPA scripts 40 (FIG. 2). RPA scripts 40 may be formulated according to any data specification known in the art, for instance in a version of an extensible markup language (XML), Javascript Object Notation (JSON), or a programming language such as C #, Visual Basic, Java, etc. Alternatively, RPA scripts 40 may be formulated in an RPA-specific version of bytecode, or even as a sequence of instructions formulated in a natural language such as English, Spanish, Japanese, etc. In some embodiments, scripts 40 are pre-compiled into a set of native processor instructions (e.g., machine code.)

A skilled artisan will appreciate that RPA design application 30 may comprise multiple components/modules, which may or may not execute on the same computer/physical machine. In one example illustrating a cloud computing embodiment of the present invention, RPA design application 30 may execute in a client-server configuration, wherein one component of application 30 may expose a robot design interface to a user of a client computer, and another component of application 30 executing on a server computer may assemble the robot workflow and formulate/output RPA script 40. For instance, a developer may access the robot design interface via a web browser executing on the client computer, while the software processing the user input received at the client computer actually executes on the server computer.

Once formulated, scripts 40 may be executed by a set of robots 12a-c (FIG. 1), which may be further controlled and coordinated by an orchestrator 14. Robots 12a-c and orchestrator 14 may each comprise a plurality of computer programs, which may or may not execute on the same physical machine. Exemplary commercial embodiments of robots 12a-c and orchestrator 14 include UiPath Robots™ and UiPath Orchestrator™, respectively. Types of robots 12a-c include, but are not limited to, attended robots, unattended robots, development robots (similar to unattended robots, but used for development and testing purposes), and nonproduction robots (similar to attended robots, but used for development and testing purposes).

Attended robots are triggered by user events and/or commands and operate alongside a human operator on the same computing system. In some embodiments, attended robots can only be started from a robot tray or from a command prompt and thus cannot be controlled from orchestrator 14 and cannot run under a locked screen, for example. Unattended robots may run unattended in remote virtual environments and may be responsible for remote execution, monitoring, scheduling, and providing support for work queues.

Orchestrator 14 may have various capabilities including, but not limited to, provisioning, deployment, configuration, queueing, monitoring, logging, and/or providing interconnectivity for robots 12a-c. Provisioning may include creating and maintaining connections between robots 12a-c and orchestrator 14. Deployment may include ensuring the correct delivery of software (e.g, RPA scripts 40) to robots 12a-c for execution. Configuration may include maintenance and delivery of robot environments and workflow configurations. Queueing may include providing management of queues and queue items. Monitoring may include keeping track of robot state and maintaining user permissions. Logging may include storing and indexing logs to a database and/or another storage mechanism (e.g., SQL, ElasticSearch™, Redis™) Orchestrator 14 may further act as a centralized point of communication for third-party solutions and/or applications.

FIG. 2 shows exemplary components of a robot 12 and orchestrator 14 according to some embodiments of the present invention. An exemplary RPA robot is constructed using a Windows™ Workflow Foundation Application Programming Interface from Microsoft, Inc. Robot 12 may comprise a set of executors 22 and an RPA agent 24. Robot executors 22 are configured to receive RPA script 40 indicating a sequence of activities that mimic the actions of a human operator carrying out a business process, and to actually perform the respective sequence of activities on the respective client machine. In some embodiments, robot executor(s) 22 comprise an interpreter (e.g., a just-in-time interpreter or compiler) configured to translate RPA script 40 into a runtime package comprising processor instructions for carrying out the operations described in the respective script. Executing script 40 may thus comprise executor(s) 22 translating RPA script 40 and instructing a processor of the respective host machine to load the resulting runtime package into memory and to launch the runtime package into execution.

RPA agent 24 may manage the operation of robot executor(s) 22. For instance, RPA agent 24 may select tasks/scripts for execution by robot executor(s) 22 according to an input from a human operator and/or according to a schedule. Agent 24 may start and stop jobs and configure various operational parameters of executor(s) 22. When robot 12 includes multiple executors 22, agent 24 may coordinate their activities and/or inter-process communication. RPA agent 24 may further manage communication between RPA robot 12 and orchestrator 14 and/or other entities.

In some embodiments executing in a Windows™ environment, robot 12 installs a Microsoft Windows™ Service Control Manager (SCM)-managed service by default. As a result, such robots can open interactive Windows™ sessions under the local system account and have the processor privilege of a Windows™ service. For instance, a console application may be launched by a SCM-managed robot. In some embodiments, robot 12 can be installed at a user level of processor privilege (user mode, ring 3.) Such a robot has the same rights as the user under which the respective robot has been installed. For instance, such a robot may launch any application that the respective user can. On computing systems that support multiple interactive sessions running simultaneously (e.g., Windows™ Server 2012), multiple robots may be running at the same time, each in a separate Windows™ session, using different usernames.

In some embodiments, robot 12 and orchestrator 14 may execute in a client-server configuration. It should be noted that the client side, the server side, or both, may include any desired number of computing systems (e.g., physical or virtual machines) without deviating from the scope of the invention. In such configurations, robot 12 including executor(s) 22 and RPA agent 24 may execute on a client side. Robot 12 may run several workflows concurrently. RPA agent 24 (e.g., a Windows™ service) may act as a single client-side point of contact of executors 22. Agent 24 may further manage communication between robot 12 and orchestrator 14. In some embodiments, communication is initiated by agent 24, which may open a WebSocket channel to orchestrator 14. Agent 24 may subsequently use the channel to transmit notifications regarding the state of each executor 22 to orchestrator 14. In turn, orchestrator 14 may use the channel to transmit acknowledgements, job requests, and other data such as RPA scripts 40 to robot 12.

Orchestrator 14 may execute on a server side, possibly distributed over multiple physical machines. In one such embodiment, orchestrator 14 may include an orchestrator user interface (UI) 17 which may be a web application, and a set of service modules 19. Service modules 19 may further include a set of Open Data Protocol (OData) Representational State Transfer (REST) Application Programming Interface (API) endpoints, and a set of service APIs/business logic. A user may interact with orchestrator 14 via orchestrator UI 17 (e.g., by opening a dedicated orchestrator interface on a browser), to instruct orchestrator 14 to carry out various actions, which may include for instance starting jobs on robot 12, creating robot groups, assigning workflows to robots, adding/removing data in queues, scheduling jobs to run unattended, analyzing logs per robot or workflow, etc. Orchestrator UI 17 may use Hypertext Markup Language (HTML), JavaScript (JS), or any other data format known in the art.

Orchestrator 14 may carry out actions requested by the user by selectively calling service APIs/business logic. In addition, orchestrator 14 may use the REST API endpoints to communicate with robot 12. The REST API may include configuration, logging, monitoring, and queueing functionality. The configuration endpoints may be used to define and configure application users, permissions, robots, assets, releases, etc. Logging REST endpoints may be used to log different information, such as errors, explicit messages sent by the robots, and other environment-specific information, for instance. Deployment REST endpoints may be used by robots to query the version of RPA script 40 to be executed. Queueing REST endpoints may be responsible for queues and queue item management, such as adding data to a queue, obtaining a transaction from the queue, setting the status of a transaction, etc. Monitoring REST endpoints may monitor the web application component of orchestrator 14 and RPA agent 24.

In some embodiments, RPA environment 10 (FIG. 1) further comprises a database server 16 connected to an RPA database 18. In an embodiment wherein server 16 is provisioned on a cloud computing platform, server 16 may be embodied as a database service, e.g., as a client having a set of database connectors. Database server 16 is configured to selectively store and/or retrieve data related to RPA environment 10 in/from database 18. Such data may include configuration parameters of various robots 12a-c, robot groups, as well as data characterizing workflows executed by various robots, and data characterizing users, roles, schedules, queues, etc. Another exemplary category of data stored and/or retrieved by database server 16 includes data characterizing the current state of each executing robot. Yet another exemplary category of data includes messages logged by various robots during execution. Database server 16 and database 18 may employ any data storage protocol and format known in the art, such as structured query language (SQL), ElasticSearch™, and Redis™, among others. In some embodiments, data is gathered and managed by orchestrator 14, for instance via logging REST endpoints. Orchestrator 14 may further issue structured queries to database server 16.

In some embodiments, RPA environment 10 (FIG. 1) further comprises communication channels/links 15a-e interconnecting various members of environment 10. Such links may be implemented according to any method known in the art, for instance as virtual network links, virtual private networks (VPN), or end-to-end tunnels. Some embodiments further encrypt data circulating over some or all of links 15a-e.

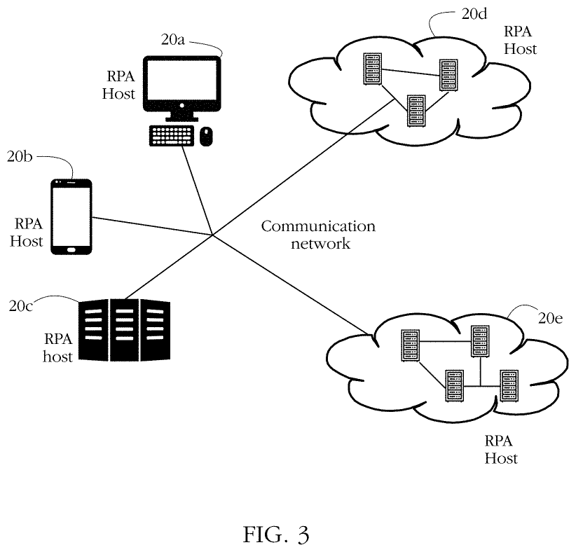

A skilled artisan will understand that various components of RPA environment 10 may be implemented and/or may execute on distinct host computer systems (physical appliances and/or virtual machines.) FIG. 3 shows a variety of such RPA host systems 20a-e according to some embodiments of the present invention. Each host system 20a-e represents a computing system (e.g. an individual computing appliance, or a set of interconnected computers) having at least a hardware processor, a memory unit and a network adapter enabling the respective RPA host to connect to a computer network and/or to other computing devices. Exemplary RPA hosts 20a-c include personal computers, laptop and tablet computers, mobile telecommunication devices (e.g., smartphones), and corporate mainframe computers, among others. Other exemplary hosts illustrated as hosts 20d-e include cloud computing platforms such as server farms operated by Amazon™ AWS and Microsoft™ Azure™. A cloud computing platform comprises a plurality of interconnected server computer systems centrally-managed according to a platform-specific protocol. Clients may interact with such cloud computing platforms using platform-specific interfaces/software layers/libraries (e.g., software development kits—SDKs, plugins, etc.) and/or a platform-specific syntax of commands. Exemplary platform-specific interfaces include the Azure™ SDK and AWS™ SDK, among others.

FIG. 4 shows exemplary software executing on an RPA host 20 according to some embodiments of the present invention. The illustrated RPA host 20 generically represents any of RPA hosts 20a-e in FIG. 3. In some embodiments, beside an RPA robot 12, RPA host 20 executes an operating system (OS) 32 and an instance of an RPA target application 34, i.e., the software application targeted for automation by robot 12. In some embodiments that employ hardware virtualization technologies, some or all of the illustrated components may execute within a virtual machine (VM).

OS 32 may comprise any widely available operating system such as Microsoft Windows™ MacOS™, Linux™, iOS™, or Android™, among others, comprising a software layer that interfaces between application 34 and the hardware of RPA host 20. RPA target application 34 generically represents any computer program used by a human operator to carry out a task. Exemplary applications 34 include, among others, a word processor, a spreadsheet application, a graphics application, a browser, a social media application, a gaming application, and an electronic communication application.

In some embodiments, robot 12 carries out user interface automation activities by interfacing with a set of drivers 36 executing on the respective host. Driver(s) 36 generically represent software modules that carry low-level operations such as moving a cursor on screen, registering and/or executing mouse, keyboard, and/or touchscreen events, detecting a current posture/orientation of a handheld device, detecting a current accelerometer reading, taking a photograph with a smartphone camera, etc. Some such drivers 36 form a part of operating system 30. Others may implement various application-specific aspects of a user's interaction with complex target applications 34 such as SAP™, Citrix™ virtualization software, Excel™, etc. Such drivers 36 may include, for instance, browser drivers, virtualization drivers, and enterprise application drivers, among others. Other exemplary drivers 36 include the Microsoft™ WinAppDriver, XCTest drivers from Apple, Inc., and UI Automator drivers from Google, Inc.

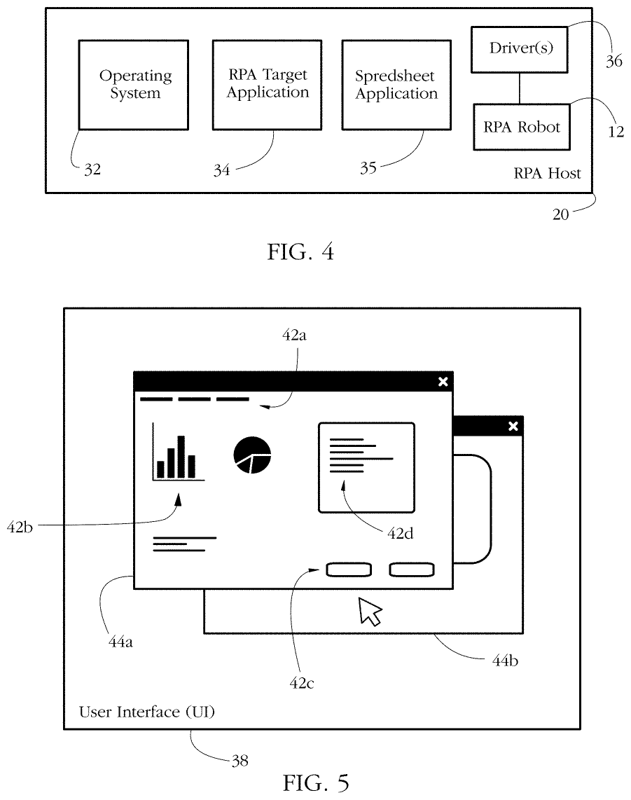

RPA target application 34 is typically configured to expose a user interface (UI). A user interface is a computer interface that enables human-machine interaction, e.g., an interface configured to receive user input and to respond to the respective input. A common example of user interface is known as a graphical user interface (GUI), which enables human-machine interaction via a set of visual elements displayed to the user. FIG. 5 shows such an exemplary UI 38 according to some embodiments of the present invention. Illustrative UI 38 has a set of exemplary windows 44a-b and a set of exemplary UI elements including a menu indicator 42a, an icon 42b, a button 42c, and a text box 42d. Other exemplary UI elements comprise, among others, a window, a label, a form, an individual form field, a toggle, a link (e.g., a hyperlink, hypertext, or a uniform resource identifier). UI elements may display information, receive input (text, mouse events,) and/or control a functionality of software and/or the respective computer system.

Some UI elements are interactive in the sense that acting on them (e.g., clicking button 42c) triggers a behavior/reaction. Such behaviors/reactions are typically specific to the respective element or to a group of elements. For instance, clicking a save button produces a different effect to clicking a print button. The same keyboard shortcut (e.g., Ctrl-G) may have one effect when executed in one window/application, and a completely different effect when executed in another window/application. So, although the operation/action/activity is the same (executing a click, pressing a combination of keyboard keys, writing a sequence of characters, etc.), the result of the respective action may depend substantially on the operand of the respective operation. An operand is herein defined as the UI element that is acted upon by a current activity such as a click or a keyboard event, or stated otherwise, the UI element selected to receive the respective user input. The terms ‘operand’ and ‘target’ are herein used interchangeably.

Some embodiments attach a selector to each target UI element, the selector comprising a data structure that selectively identifies the respective element among the plurality of UI elements of UI interface 38. In one exemplary embodiment, the selector indicates a position of the respective UI element in an object hierarchy of UI interface 38, such as a GUI tree or DOM model. GUI object hierarchies may be encoded in computer-readable form in a language such as XML or JSON, among others. One exemplary selector may indicate that the respective UI element is a form field of a specific form displayed within a specific UI window. The selector of a target UI element may be specified at design time by including an encoding of the respective selector in an RPA script configured to carry out an activity on the respective UI element. At runtime, robot 12 may attempt to identify the target UI element within a runtime instance of the target UI according to the respective selector and possibly according to other information such as an image of the respective UI element and/or a text displayed on the respective UI element.

In some embodiments, RPA host 20 is further configured to execute an instance of a spreadsheet application 35. A spreadsheet is an electronic document wherein data is arranged in tabular form and wherein individual table cells may hold values and/or formulae for manipulating the content of the respective cell and/or of other cells of the spreadsheet. Spreadsheet application 35 comprises software configured to read, write, and otherwise manipulate spreadsheet data, for instance to calculate a content of a selected cell according to a formula associated with the respective cell. In some embodiments, spreadsheet application 35 exposes a set of user interfaces enabling a user to enter and edit spreadsheet data, to attach a formula to a selected cell, etc. Exemplary spreadsheet applications 35 include, among others, Microsoft Excel™ Numbers™ from Apple, Inc., and the open source OpenOffice Calc™ and LibreOffice Calc™ from the Apache Foundation and the Document Foundation, respectively. Other exemplary spreadsheet applications 35 include web-based services such as Google Sheets™, EtherCalc™ and Smartsheet™, among others. Members of this category of spreadsheet applications do not execute on the local RPA host but on a remote server instead; for such embodiments, invoking spreadsheet application 35 may comprise invoking a remote server script by using a local web browser to send an access request to the respective remote server.

In some embodiments, spreadsheet application 35 and RPA target application 34 may coincide, i.e., robot 12 may be specifically configured to automate spreadsheet activities such as entering and/or reading data from/to a user-provided spreadsheet, and may effectively invoke the functionality of spreadsheet application 35 (e.g., via driver 36) to carry out the respective activities.

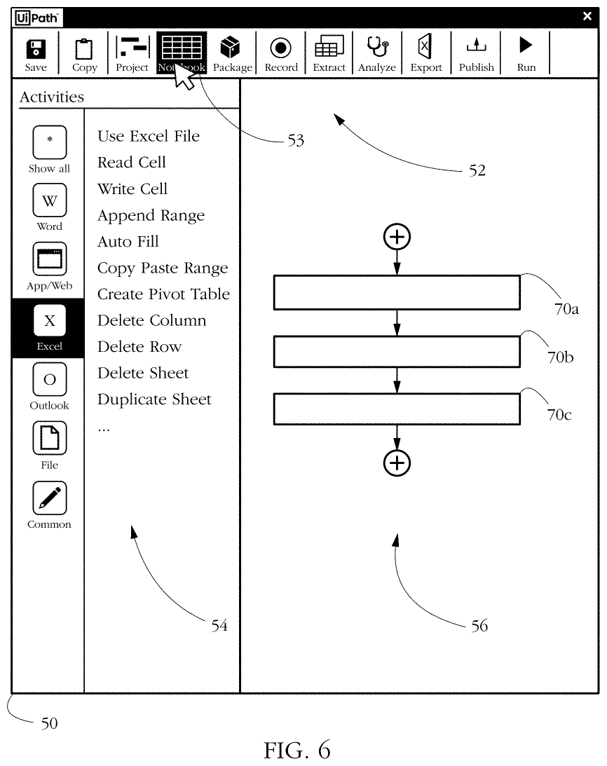

FIG. 6 shows an exemplary robot design interface 50 exposed by RPA design application 30 according to some embodiments of the present invention. Interface 50 may be configured to enable a user to program RPA robot 12 by using a set of intuitive visual tools, instead of coding per se. For instance, interface 50 may enable the user to build a robot from a set of individual building blocks assembled in sequence. Such building blocks may comprise various activities, such as opening an instance of RPA target application 34, clicking on a UI element of application 34, filling out a form field, etc.

In one example illustrated in FIG. 6, robot design interface 50 comprises a main menu/ribbon 52 including a plurality of menu items for performing actions such as opening, saving, and managing robot projects, recording a set of actions to be performed by robot 12, and executing robot 12, among others. Robot design interface 50 may further expose an activity menu 54 listing a plurality of available activities for building software robots. For convenience, activity menu 54 may be organized into a hierarchy of submenus. In the example of FIG. 6, available activities are organized into submenus according to a type of target application (e.g., activities for interacting with Microsoft Word™ are grouped together into a submenu, while activities for interacting with a web browser are grouped into another submenu.) For instance, FIG. 6 shows an expanded activity submenu labeled ‘Excel’, comprising activities for interacting with spreadsheets. Such exemplary spreadsheet activities may comprise reading from and writing data to spreadsheet cells, inserting and/or deleting rows and columns, adding/deleting/renaming spreadsheets, creating pivot tables, sorting tables, filtering, running various spreadsheet macros, etc. Other grouping criteria may be used to organize activity menu 54, for instance, activities may be grouped according to a type of target object: file-related activities such as opening, creating, deleting, and downloading a file may be grouped together into a submenu, while image-related activities may be grouped into another submenu.

In some embodiments, robot design interface 50 further comprises a workflow area configured to display a workflow 56 comprising a visual representation of a set of already selected robot activities arranged in sequence according to a desired order of execution of the respective activities. In the example of FIG. 6, individual activities are represented by activity containers 70-a-c connected by arrows in the manner of a computer flowchart. In some embodiments, the user may access each individual activity by clicking inside the respective activity container 70a-c. In response to detecting such a click, some embodiments may expose an activity configuration interface enabling the user to configure various aspects of the respective activity, as further detailed below.

In some embodiments, robot design interface 50 exposes a dedicated UI element (e.g., button) for invoking a universal helper spreadsheet. In the exemplary interface illustrated in FIG. 6, a helper spreadsheet button 53 is part of main menu/ribbon 52; a skilled artisan will understand that this illustrative placement is not meant to be limiting. In alternative embodiments, the helper spreadsheet may be invoked via other means, for instance via a dropdown menu, an icon placed in an additional toolbar/window, etc. In some embodiments, invoking the universal helper spreadsheet comprises invoking an instance of spreadsheet application 35 (e.g., Microsoft Excel™) to display the helper spreadsheet to the user.

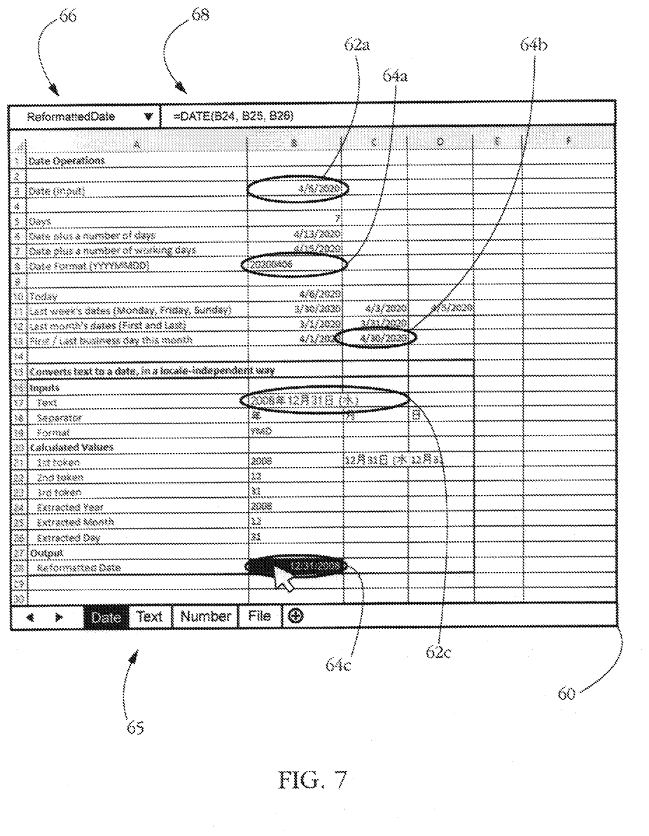

FIG. 7 shows an exemplary universal helper spreadsheet 60 according to some embodiments of the present invention. Spreadsheet 60 comprises a plurality of cells individually accessible for reading and/or writing. Each cell may hold a value and/or a formula for calculating the respective value. In the illustrated example, spreadsheet cells are organized in tabular form, each cell uniquely identified by a row label (e.g., a number) and a column label (e.g., a set of letters.) However, these aspects are not meant to be limiting. Some cells may be identified by a cell name. In some embodiments, selecting a cell, for instance by clicking it or hovering the mouse pointer over it, may indicate the cell name of the respective cell in a dedicated region of spreadsheet 60 and/or of robot design interface 50. In the illustrated example, cell 64c may be identified as cell B28 and/or according to a cell name 66 (‘ReformattedDate’).

In some embodiments, cells of spreadsheet 60 may be divided into at least two categories: input cells and output cells. Input cells may receive any value and do not have an attached formula. However, the formatting of the respective value may be constrained, for instance by the data type of the respective value (e.g., the formatting of dates may differ from the formatting of numbers or plain text.) Exemplary input cells include a cell 62a configured to receive an arbitrary, user-provided calendar date, and an input cell 62c configured to receive a text string. In contrast, the value contained within an output cell is not arbitrary, but automatically determined by applying a pre-defined operation to a value of a selected input cell and/or to other data. The pre-defined operation may include a mathematical operation (e.g., addition, exponentiation, etc.), a re-formatting operation (e.g., changing 04/28/20 into 28-Apr-2020), an application of a pre-defined computer function, module, subroutine, etc. The pre-defined operation associated with an output cell may be indicated via a formula or via an expression formulated in a programming language; such formulae are interpreted by spreadsheet application 35 at runtime. In the exemplary helper spreadsheet illustrated in FIG. 7, output cell 64c has an associated formula 68 comprising a predefined function ‘DATE’ configured to receive an ordered sequence of three inputs. The value of output cell 64c is therefore determined by applying formula 68 to the values of cells B24, B25, and B26. In the illustrated example, the current value of cells B24, B25, and B26 is in turn calculated according to the current value of input cell 62c. Other exemplary output cells include cell 64a, which transforms the current value of input cell 62a into another pre-specified date format (YYYYMMDD). Yet another exemplary output cell 64b has an associated formula which calculates the date of the last business day of the current month, and displays it in a pre-defined date format.

In some embodiments, universal helper spreadsheet 60 comprises multiple cell sheets individually accessible via dedicated UI controls (e.g., buttons, tabs, etc.) and identified by unique labels/sheet names 65. Cells may be grouped into separate sheets according to various criteria, for instance according to a type of data manipulation/formula associated with the respective cells or according to a data type of the respective cells. In one example, a subset of cells configured to operate with dates and another subset of cells configured to operate with numbers are grouped into separate sheets.

Some cells of universal helper spreadsheet 60 are pre-filled with data and/or formulae which are not user-supplied, but instead provided as part of a software distribution of RPA design application 30. The term ‘universal’ is used herein to indicate that universal helper spreadsheet 60 is not user-specific but distributed identically to a substantial proportion of users (e.g., all users) of RPA design application 30. In one example, the same spreadsheet 60 is delivered across multiple user accounts for application 30, e.g., to all user accounts associated with a workgroup or organization. In another example, spreadsheet 60 is made available in identical form to all users of a particular version of application 30. In some embodiments, helper spreadsheet 60 is delivered to users as part of a software installation package which, when executed on a local computer of the user, installs and/or configures the local instance of RPA design application 30. In an alternative embodiment, helper spreadsheet 60 may be downloaded as an optional add-on or upgrade that extends the already-installed functionality of RPA design application 30. In an embodiment wherein universal helper spreadsheet 60 is invoked via a spreadsheet-processing application that executes on a remote server computer (e.g., in a configuration commonly known as “in the cloud”) the network location of helper spreadsheet 60 may not be user-specific or otherwise indicated by the user. Instead, such a network location may be common to a substantial proportion of users.

The term ‘helper’ is used herein to indicate that the intended use of universal helper spreadsheet 60 is in assisting users in designing various RPA robots, and not specifically in automating spreadsheet activities. Stated otherwise, the main thrust of automations assisted by spreadsheet 60 is not directed at reading from and/or writing to spreadsheet 60 per se. Instead, helper spreadsheet 60 is only used as a tool to achieve some other automation task.

Some examples of activities assisted by spreadsheet 60 include re-formatting dates (e.g., from Japanese to American or European and vice-versa), determining various calendar features (e.g., the current week number, the date of the last workday of the current month, when the second week of September starts, etc.) and re-formatting numbers (e.g., changing the decimal separator according to the locale), among others. Some embodiments rely on the observation that popular spreadsheet applications typically have pre-defined formulae and/or functions for such operations. Therefore, some embodiments populate universal helper spreadsheet 60 with a collection of formulae for performing standard useful operations with dates, currencies, numbers, files, etc., as illustrated in FIG. 7.

Exemplary date-related formulae included in universal helper spreadsheet 60 comprise a formula for calculating the date of a first and last business day of a month (e.g., according to a content of an input cell configured to receive an indicator of the respective month), a formula for re-formatting a date in a specific format, formulae for calculating a number of days, working days, weeks, etc. elapsed since a specific reference date (e.g., the content of a specific input cell). Other exemplary formulae included in spreadsheet 60 may be configured to process a target character string (e.g., piece of text) supplied to a specific input cell. Such formulae may include formulae for dividing the respective character string into tokens according to specific token separators (for instance to identify a first name and a last name within a full name, to break a filesystem path into a filename indicator and a folder indicator, to identify the file extension of a file, etc.), re-arranging certain tokens extracted from the target character string (e.g., to reformat a name so the last name appears first), to remove specific characters from the target character string, counting the characters within the target character string, trimming the target character string to a specified length, determining whether the target character string contains a specified substring, replacing a specified substring with another specified substring, etc. Exemplary number-related formulae of spreadsheet 60 may include, among others, formulae for re-formatting a number according to various locales (e.g., by replacing a decimal separator and/or a thousands separator), determining an integer part and/or a decimal part of a number, changing a decimal representation of a number to include fewer or more decimal places, etc.

Some embodiments allow the developer to edit and/or expand universal helper spreadsheet 60 to adapt it to the needs of a particular automation. For instance, the user may add sheets, add input/output cells, and move cells between sheets. The user may further input new formulae into output cells. An updated version of the spreadsheet 60 may then be made available to RPA robot 12 at runtime.

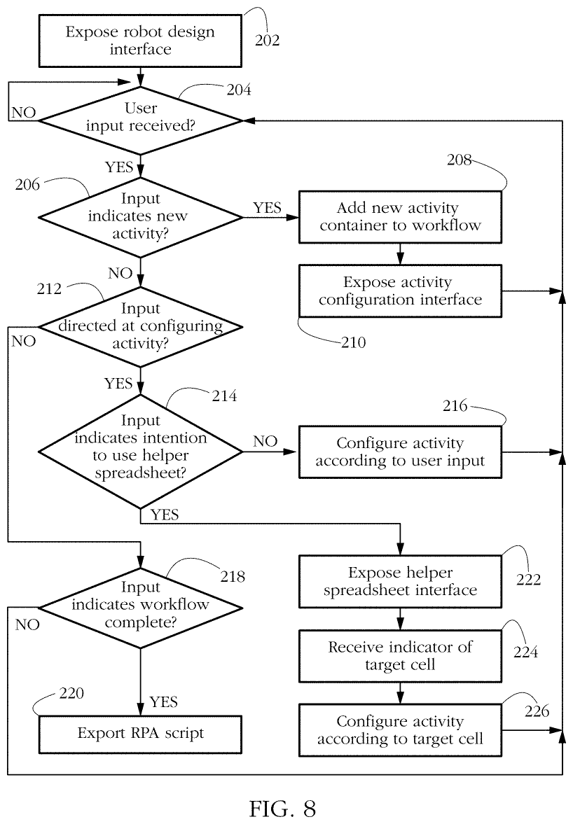

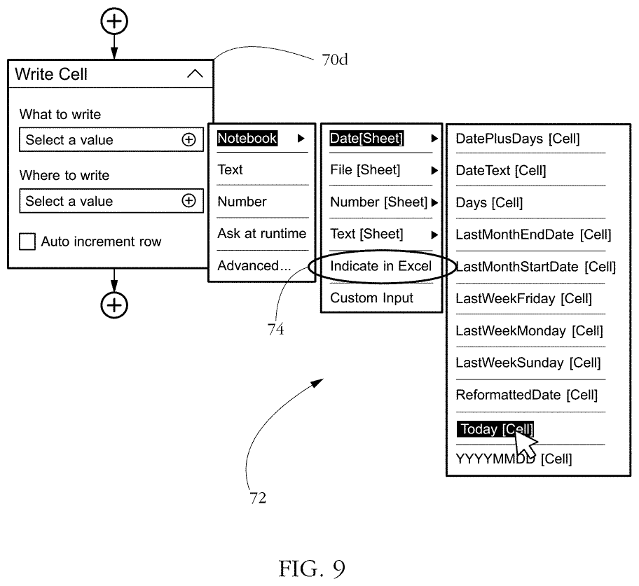

FIG. 8 shows an exemplary sequence of steps carried out by RPA design application 30 in a process of designing an RPA robot according to some embodiments of the present invention. A step 202 may expose robot design interface 50 to the user (see exemplary interface illustrated in FIG. 6). Application 30 may then wait for user input. When a user input is detected, for instance when the user interacts with one of the menus of interface 50, a step 206 determines whether the received input indicates a request to add a new activity to a current workflow. When yes (for instance in response to the user selecting an item from activity menu 54), a sequence of steps 208-210 may add a new activity container to the current workflow (see e.g., containers 70a-c in FIG. 6), and expose an activity configuration interface enabling the user to set activity-specific parameters for the respective activity. FIG. 9 shows an exemplary activity configuration interface displayed within an activity container 70d. The illustrated activity comprises writing a value to a spreadsheet cell. Its configurable parameters include, among others, a content of the write activity (what to write) and a target of the write activity (where to write, i.e., which spreadsheet cell should receive the respective content.) Such parameters may vary according to the type of activity. For instance, configurable parameters of a mouse click activity may include a target UI element (i.e., where to click), and a type of mouse click (single click, double click, right click, etc.), among others.

A step 212 determines whether the received user input is directed at configuring an RPA activity. When yes (e.g., when the user has interacted with a control for setting an activity parameter, such as the circled plus sign next to ‘Select a value’ in the exemplary activity configuration interface illustrated in FIG. 9), a further step 214 may determine whether the respective input indicates a user's intention to use universal helper spreadsheet 60 to configure the respective activity. In some embodiments, robot design interface 50 may expose a dedicated control (e.g., a button, a menu item) for interacting with spreadsheet 60; a user input comprising the user activating the respective control may be an indication that the user is trying to call on universal helper spreadsheet 60. When yes, in a step 222, RPA design application 30 may expose a helper spreadsheet interface configured to enable the user to interact with helper spreadsheet 60.

In some embodiments, step 222 comprises invoking an instance of spreadsheet application 35 (e.g., Microsoft Excel™) to display universal helper spreadsheet 60, thus enabling the user to indicate a target input/output cell of spreadsheet 60 directly via the interface exposed by spreadsheet application 35. Alternatively, step 222 may display a cell selection menu 72 as illustrated in FIG. 9, enabling the user to indicate a target cell of helper spreadsheet 60 by selecting an item of menu 72. In the illustrated example, clicking on the circled plus symbol next to ‘Select a value’ may progressively unfold a cascading cell selection menu enabling the user to select helper spreadsheet 60, then listing available cell sheets of spreadsheet 60 (e.g., by their respective sheet label/name), then listing a set of available cells of the selected sheet (e.g., by their respective cell label/name.) Exemplary menu 72 further comprises an item 74 ‘Indicate in Excel’ which, when selected by the user, may invoke spreadsheet application 35 (in this case, Microsoft Excel™) to display helper spreadsheet 60, thus allowing the user to directly indicate a target cell in the interface provided by spreadsheet application 35.

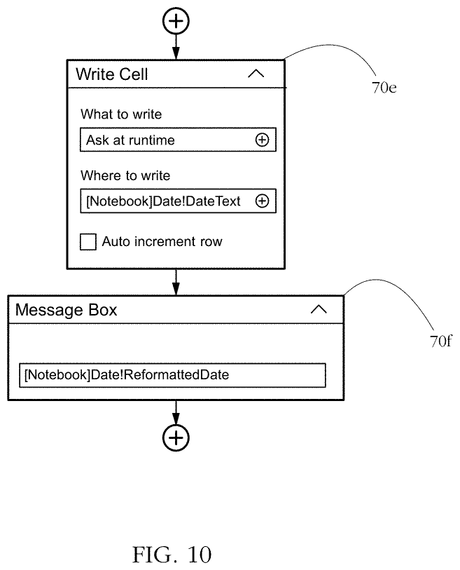

In a sequence of steps 224-226 (FIG. 8), RPA design application 30 may receive an indicator of a target cell of helper spreadsheet 60, and may configure the respective activity according to the selected target cell. In one such example illustrated in FIG. 9, by selecting the highlighted menu item “Today [Cell]”, the user instructs the robot to read the current value of the “Today” cell from the “Date” sheet of helper spreadsheet 60. Another example of configuring activities according to universal helper spreadsheet 60 is illustrated in FIG. 10, which shows a snippet of an exemplary workflow comprising two activity containers 70e and 70f. Container 70e represents an activity of writing to a spreadsheet cell, wherein the robot is configured to ask for a date and write the respective date to the “DateText” cell of the “Date” sheet of helper spreadsheet 60 (denoted herein as “Notebook”.) In turn, container 70f represents an activity of displaying a message box to the user, the message box showing a content of the “ReformattedDate” cell of the “Date” sheet of helper spreadsheet 60. Stated otherwise, in the example of FIG. 10, the user is instructing the robot to use helper spreadsheet 60 for the purpose of re-formatting the date.

When step 214 (FIG. 8) outputs a NO, a step 216 may configure the current activity in a manner which does not involve helper spreadsheet 60. For instance, step 216 may indicate a target UI element for a mouse click activity, etc. When the user input received in step 204 indicates that the current robot design session is complete (step 218 produces a YES), then in a step 220 RPA design application may export RPA script 40 comprising a computer-readable encoding of the instructions for RPA robot 12.

RPA script 40 may then be transmitted to RPA robot 12 for execution. In some embodiments, an instance of universal helper spreadsheet 60 is transmitted to or otherwise made available to RPA robot 12 at runtime. For instance, RPA script 40 may comprise an encoding of universal helper spreadsheet 60 and/or of a location indicator (e.g., network address, URL) where spreadsheet 60 can be accessed remotely or downloaded from.

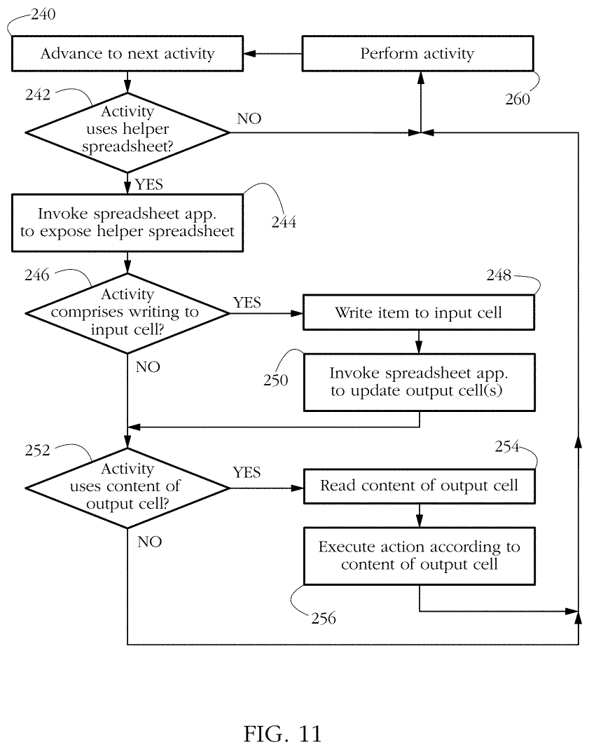

FIG. 11 shows an exemplary sequence of steps performed by robot 12 at runtime, according to some embodiments of the present invention. For each activity of the workflow, a step 242 may determine whether the current activity uses universal helper spreadsheet 60. When no, robot 12 may perform the respective activity using any methods/means known in the art (step 260.) When yes, in a step 244 RPA robot 12 may use driver(s) 36 to invoke spreadsheet application 35 executing on the local host to expose/load universal helper spreadsheet 60. When spreadsheet 60 is located remotely, step 244 may include accessing spreadsheet 60 via a communication interface and/or downloading a copy of spreadsheet 60 to local RPA host 20.

When the current activity comprises writing an item to an input cell of spreadsheet 60 (step 246 returns a YES), a step 248 may employ driver(s) 36 to identify the target input cell (for instance according to the cell name) and write the item to the respective input cell of spreadsheet 60. A step 250 may invoke spreadsheet application 35 to update the content of output cells according to the newly written item. In some embodiments, spreadsheet application 35 may update cell contents automatically. When the current activity comprises reading a content of an output cell of spreadsheet 60 (when step 252 returns a YES), in a step 254 robot 12 may identify the output cell and employ driver(s) 36 to read the content of the respective cell. A further step 256 may execute an action according to the current activity and further according to the content of the output cell.

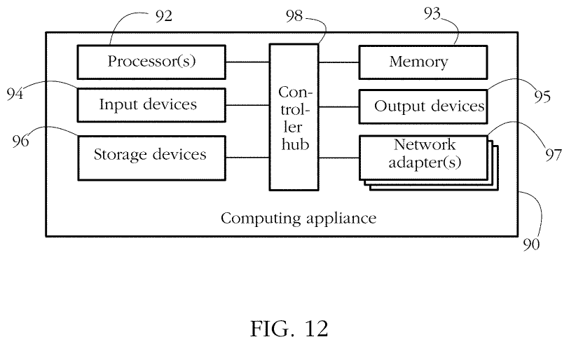

FIG. 12 shows an exemplary hardware configuration of a computing appliance 90 programmed to execute some of the methods described herein. Appliance 90 may represent any of RPA host platforms 20a-e in FIG. 3. The illustrated appliance is a personal computer; other computing devices such as servers, mobile telephones, tablet computers, and wearable computing devices may have slightly different configurations. Processor(s) 92 comprise a physical device (e.g. microprocessor, multi-core integrated circuit formed on a semiconductor substrate) configured to execute computational and/or logical operations with a set of signals and/or data. Such signals or data may be encoded and delivered to processor(s) 92 in the form of processor instructions, e.g., machine code. Processor(s) 92 may include a central processing unit (CPU) and/or an array of graphics processing units (GPU).

Memory unit 93 may comprise volatile computer-readable media (e.g. dynamic random-access memory—DRAM) storing data and/or instruction encodings accessed or generated by processor(s) 22 in the course of carrying out operations. Input devices 94 may include computer keyboards, mice, and microphones, among others, including the respective hardware interfaces and/or adapters allowing a user to introduce data and/or instructions into appliance 90. Output devices 95 may include display devices such as monitors and speakers among others, as well as hardware interfaces/adapters such as graphic cards, enabling the respective computing device to communicate data to a user. In some embodiments, input and output devices 94-95 share a common piece of hardware (e.g., a touch screen). Storage devices 96 include computer-readable media enabling the non-volatile storage, reading, and writing of software instructions and/or data. Exemplary storage devices include magnetic and optical disks and flash memory devices, as well as removable media such as CD and/or DVD disks and drives. Network adapter(s) 97 include mechanical, electrical, and signaling circuitry for communicating data over physical links coupled to an electronic communication network (e.g, FIG. 3) and/or to other devices/computer systems. Adapter(s) 97 may be configured to transmit and/or receive data using a variety of communication protocols.

Controller hub 98 generically represents the plurality of system, peripheral, and/or chipset buses, and/or all other circuitry enabling the communication between processor(s) 92 and the rest of the hardware components of appliance 90. For instance, controller hub 98 may comprise a memory controller, an input/output (I/O) controller, and an interrupt controller. Depending on hardware manufacturer, some such controllers may be incorporated into a single integrated circuit, and/or may be integrated with processor(s) 92. In another example, controller hub 98 may comprise a northbridge connecting processor 92 to memory 93, and/or a southbridge connecting processor 92 to devices 94, 95, 96, and 97.

The exemplary systems and methods described above facilitate the design/programming of RPA robots by making such activities more accessible and attractive to developers that lack a formal programming background.

Some robotic activities may comprise reading data from a source document, manipulating the extracted data in a specific way, and writing a result of the manipulation to a target document. In one exemplary use case scenario, an RPA robot needs to open a set of PDF documents comprising invoices. For each document, the robot needs to extract the date of the invoice, the client name, and the invoiced amount, and write the respective information to a spreadsheet. However, the invoices are in Japanese, while the spreadsheet is destined for an American audience. Therefore, the robot must automatically transform the extracted invoice date from a Japanese format to an American format, e.g., month/day/year. In another exemplary use case scenario, an RPA robot needs to prepare a newsletter for a European client, the newsletter comprising quarterly financial results of a few target American companies. To prepare the newsletter, the robot needs to access a webpage, scrape the required financial data off the respective webpage, and input the respective data into a set of fields of the newsletter. Since the formatting of dates and numbers differs between European and North American countries, the robot must automatically convert dates and/or numbers accordingly. In yet another use case scenario, an RPA robot needs to send out an email on the last workday of each month. To accomplish the task, the robot needs to be able to automatically determine the correct date on which to send the respective email.

Such calculations may require a level of computer programming expertise expected to exceed that of an average person, and therefore programming an RPA robot to carry out such activities may be out of reach for non-technical RPA developers. Some embodiments rely on the observation that while the average computer user is typically oblivious to the coding required for such data manipulations, he/she is likely to be acquainted with popular spreadsheet software, such as Microsoft Excel™ and Numbers™ from Apple, Inc., among others. Such spreadsheet applications typically include pre-defined functions and tools for carrying out standard manipulations such as date and number conversions. Therefore, some embodiments enable the user to employ a familiar spreadsheet tool to accomplish an RPA programming task.

In some embodiments, a robot design interface comprises a dedicated control (e.g., a button and/or a menu item) which, when activated by the developer, invokes a universal helper spreadsheet pre-filled with a plurality of formulae for performing standard data manipulations such as date and number conversions, calendar calculations, etc. The RPA developer may then use standard and familiar RPA tools to instruct the robot to write the data that needs to be converted/manipulated to an input cell of the universal helper spreadsheet, and to read a result of the conversion/manipulation from a respective output cell of the helper spreadsheet. The universal helper spreadsheet is then made available to the RPA robot at runtime.

In contrast to conventional RPA wherein automation of spreadsheet activities typically comprises the developer providing his/her own source and/or target spreadsheets, the universal helper spreadsheet according to some embodiments of the present invention is provided by the RPA design software. Stated otherwise, the helper spreadsheet is supplied in identical form to a substantial number of users (e.g., all users) of a selected version of an RPA design application. The helper spreadsheet may be distributed with an installation package for the respective RPA design software, or made accessible to users via a download/add-on/upgrade. In some embodiments, individual users are allowed to make changes to the helper spreadsheet, for instance to add their own formulae or to edit the pre-defined ones.

It will be clear to one skilled in the art that the above embodiments may be altered in many ways without departing from the scope of the invention. Accordingly, the scope of the invention should be determined by the following claims and their legal equivalents.

What is claimed is:

1. A method comprising employing at least one hardware processor of a computer system to:
expose a robotic process automation (RPA) design interface to a user, the RPA design interface comprising:
an activity menu for selecting robotic activities for interacting with user-provided spreadsheets, and
an interface element which, when activated by the user, causes the at least one hardware processor to invoke a universal helper spreadsheet comprising a standardized spreadsheet common to multiple user accounts, the universal helper spreadsheet pre-filled with a set of formulae for carrying out data manipulations;
receive a user input indicating a selected input cell and a selected output cell of the universal helper spreadsheet; and
in response, output a computer-readable specification of an RPA robot configured to:
write a data item to a runtime instance of the selected input cell,
invoke a spreadsheet application to compute a content of the runtime instance of the selected output cell, and
perform an action that mimics a computer task carried out by a human operator, the action performed according to the content of the runtime instance of the output cell.

2. The method of claim 1, wherein the selected input cell is configured to receive a date and the selected output cell comprises a formula for changing a format of the date.

3. The method of claim 1, wherein the selected input cell is configured to receive a first date and the selected output cell comprises a formula for computing a second date according to first date.

4. The method of claim 1, wherein the selected input cell is configured to receive a text string and the selected output cell comprises a formula for determining a date according to the text string.

5. The method of claim 1, wherein the selected input cell is configured to receive a number and the selected output cell comprises a formula for changing a format of the number.

6. The method of claim 5, wherein changing the format of the number comprises changing a decimal separator or a digit group separator of the number.

7. The method of claim 5, wherein changing the format of the number comprises changing a count of decimal places of the number.

8. The method of claim 1, wherein the selected input cell is configured to receive a number and the selected output cell comprises a formula for expressing the number in another unit of measurement.

9. The method of claim 1, further comprising:
in preparation for receiving the user input, displaying a cell selection menu to the user, the cell selection menu listing a plurality of cells of the universal helper spreadsheet, each of the plurality of cells referenced by a respective cell name; and
wherein the user input comprises an item selected from the cell selection menu.

10. A computer system comprising at least one hardware processor configured to:
expose a robotic process automation (RPA) design interface to a user, the RPA design interface comprising:
an activity menu for selecting robotic activities for interacting with user-provided spreadsheets, and
an interface element which, when activated by the user, causes the at least one hardware processor to invoke a universal helper spreadsheet comprising a standardized spreadsheet common to multiple user accounts, the universal helper spreadsheet pre-filled with a set of formulae for carrying out data manipulations;
receive a user input indicating a selected input cell and a selected output cell of the universal helper spreadsheet; and
in response, output a computer-readable specification of an RPA robot configured to:
write a data item to a runtime instance of the selected input cell,
invoke a spreadsheet application to compute a content of the runtime instance of the selected output cell, and
perform an action that mimics a computer task carried out by a human operator, the action performed according to the content of the runtime instance of the output cell.

11. The computer system of claim 10, wherein the selected input cell is configured to receive a date and the selected output cell comprises a formula for changing a format of the date.

12. The computer system of claim 10, wherein the selected input cell is configured to receive a first date and the selected output cell comprises a formula for computing a second date according to first date.

13. The computer system of claim 10, wherein the selected input cell is configured to receive a text string and the selected output cell comprises a formula for determining a date according to the text string.

14. The computer system of claim 10, wherein the selected input cell is configured to receive a number and the selected output cell comprises a formula for changing a format of the number.

15. The computer system of claim 14, wherein changing the format of the number comprises changing a decimal separator or a digit group separator of the number.

16. The computer system of claim 14, wherein changing the format of the number comprises changing a count of decimal places of the number.

17. The computer system of claim 10, wherein the selected input cell is configured to receive a number and the selected output cell comprises a formula for expressing the number in another unit of measurement.

18. The computer system of claim 10, wherein the at least one hardware processor is further configured to:
in preparation for receiving the user input, display a cell selection menu to the user, the cell selection menu listing a plurality of cells of the universal helper spreadsheet, each of the plurality of cells referenced by a respective cell name; and
wherein the user input comprises an item selected from the cell selection menu.

19. The computer system of claim 10, comprising a client computer and a cloud server computer communicatively coupled to the client computer, wherein:
the client computer is configured to expose the RPA design interface to the user and to receive the user input indicating the selected input and output cells; and
the cloud server computer is configured to receive an indicator of the selected input and output cells from the client computer, and in response, to output the computer-readable specification of the RPA robot.

20. A non-transitory computer-readable medium system storing instructions which, when executed by at least one hardware processor of a computer system, cause the computer system to:
expose a robotic process automation (RPA) design interface to a user, the RPA design interface comprising:
an activity menu for selecting robotic activities for interacting with user-provided spreadsheets, and
an interface element which, when activated by the user, causes the at least one hardware processor to invoke a universal helper spreadsheet comprising a standardized spreadsheet common to multiple user accounts, the universal helper spreadsheet pre-filled with a set of formulae for carrying out data manipulations;
receive a user input indicating a selected input cell and a selected output cell of the universal helper spreadsheet; and
in response, output a computer-readable specification of an RPA robot configured to:
write a data item to a runtime instance of the selected input cell,
invoke a spreadsheet application to compute a content of the runtime instance of the selected output cell, and
perform an action that mimics a computer task carried out by a human operator, the action performed according to the content of the runtime instance of the output cell.
